(19) United States
(12) Patent Application Publication
(10) Pub. No.: US 2010/0133659 A1
(43) Pub. Date: Jun. 3, 2010

(54) SEMICONDUCTOR DEVICE AND METHOD OF MANUFACTURING SEMICONDUCTOR INTEGRATED CIRCUIT CHIP

(75) Inventors: Akio Hara, Tokyo (JP); Toyoji Sawada, Tokyo (JP); Tsuyoshi Koyashiki, Tokyo (JP); Hironori Fukaya, Tokyo (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU MICROELECTRONICS LIMITED, Tokyo (JP)

(21) Appl. No.: 12/578,901

(22) Filed: Oct. 14, 2009

(30) Foreign Application Priority Data
Dec. 1, 2008 (JP) 2008-306509

(51) Int. Cl. H01L 23/544; H01L 21/78

(52) U.S. Cl. 257/618; 438/463; 257/E23.179; 257/E21.599

(57) ABSTRACT

A semiconductor device including a plurality of circuit regions formed in a semiconductor substrate and a scribe region formed around the circuit regions for separating the respective circuit regions, the scribe region having a plurality of laminated interlayer films including a plurality of metal films and an optically-transparent insulation film formed between and on the plurality of metal films, wherein a first metal film included in a first upper interlayer film of the plurality of interlayer films is positionally offset in a vertical direction to a second metal film included in a second lower interlayer film under the first interlayer film.

### CROSS REFERENCE TO RELATED APPLICATIONS

This application is based upon and claims the benefit of priority from the prior Japanese Patent Application No. 2008-306509 filed on Dec. 1, 2008, the entire contents of which are incorporated herein by reference.

### FIELD

The described embodiments relate to a semiconductor device and a method of manufacturing a semiconductor integrated circuit chip.

### BACKGROUND

Japanese Laid-open Patent Publication No. 2005-317866 describes that when a semiconductor device is manufactured, a semiconductor substrate is partitioned to chip regions and integrated circuits and the like are formed inside the chip regions. Then, chips are obtained by executing dicing along a scribe region located between the chip regions after the integrated circuits and the like are formed. Japanese Laid-open Patent Publication No. 2004-221286 describes that dicing is executed by radiating a laser beam to metal films formed in a scribe region. Note that the metal films in the scribe region are formed to uniformly execute polishing which is mainly chemical mechanical polishing (CMP).

A configuration of a conventional scribe region will be explained. FIGS. 1A and 1B are views of a configuration of an example of the conventional scribe region. Note that FIG. 1B is a sectional view along a line I-I of FIG. 1A. In the example, a scribe region 103 is located between a first chip region 101 and a second chip region 102. In the scribe region 103, an insulation film 122 is formed on a substrate 121, and metal films 111, which extend parallel to the scribe region 103, are formed on the insulation film 122. An insulation film 123, which covers the metal films 111, is formed on the insulation film 122, and metal films 112, which extend parallel to the scribe region 103, are formed on the insulation film 123. Further, an insulation film 124, which covers the metal films 112, is formed on the insulation film 123. Note that the metal films 112 and the metal films 111 overlap with each other when viewed on a plane. This configuration has a purpose of making a design easy.

FIGS. 2A and 2B are views of a configuration of another example of the conventional scribe region. Note that FIG. 2B is a sectional view along a line I-I of FIG. 2A. In the example, an insulation film 122 is formed on a substrate 121 in a scribe region 103, and island-shaped metal films 113 are formed on the insulation film 122. Further, an insulation film 123, which covers the metal films 113, is formed on the insulation film 122, and island-shaped metal films 114 are formed on the insulation film 123. Further, an insulation film 124, which covers the metal films 114, is formed on the insulation film 123. Note that the metal films 114 and the metal films 113 overlap with each other when viewed on a plane. This configuration also has a purpose of making a design easy.

### SUMMARY

According to an aspect of the embodiment, a semiconductor device includes, a plurality of circuit regions formed in a semiconductor substrate; and a scribe region formed around the circuit regions for separating the respective circuit regions, the scribe region having a plurality of laminated interlayer films including a plurality of metal films and an optically-transparent insulation film formed between and on the plurality of metal films, wherein a first metal film included in a first upper interlayer film of the plurality of interlayer films is positionally offset in a vertical direction to a second metal film included in a second lower interlayer film under the first interlayer film.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIGS. 1A and 1B are views of a configuration of an example of a conventional scribe region;

FIGS. 2A and 2B are views of a configuration of another example of the conventional scribe region;

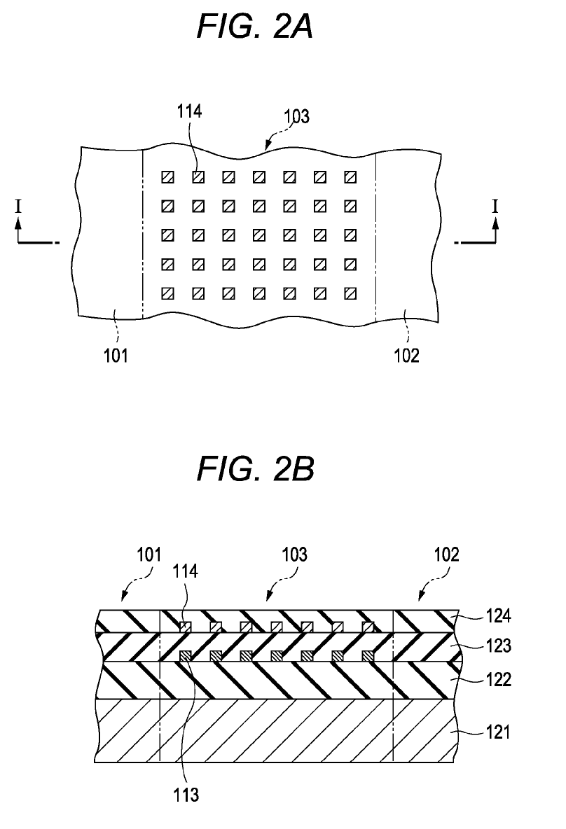

FIGS. 3A and 3B are views of a semiconductor device according to a first embodiment;

FIGS. 4A to 4C are sectional views of a method of manufacturing a semiconductor integrated circuit chip in a sequence of steps;

FIGS. 5A and 5B are views of a semiconductor device according to a second embodiment;

FIGS. 6A and 6B are views of a semiconductor device according to a third embodiment;

FIGS. 7A and 7B are views of a semiconductor device according to a fourth embodiment;

FIG. 8 is a sectional view of a semiconductor device according to a fifth embodiment; and

FIG. 9 is a sectional view of a semiconductor device according to a sixth embodiment.

### DESCRIPTION OF EMBODIMENTS

Embodiments will be explained below in detail referring to the accompanying drawings.

### First Embodiment

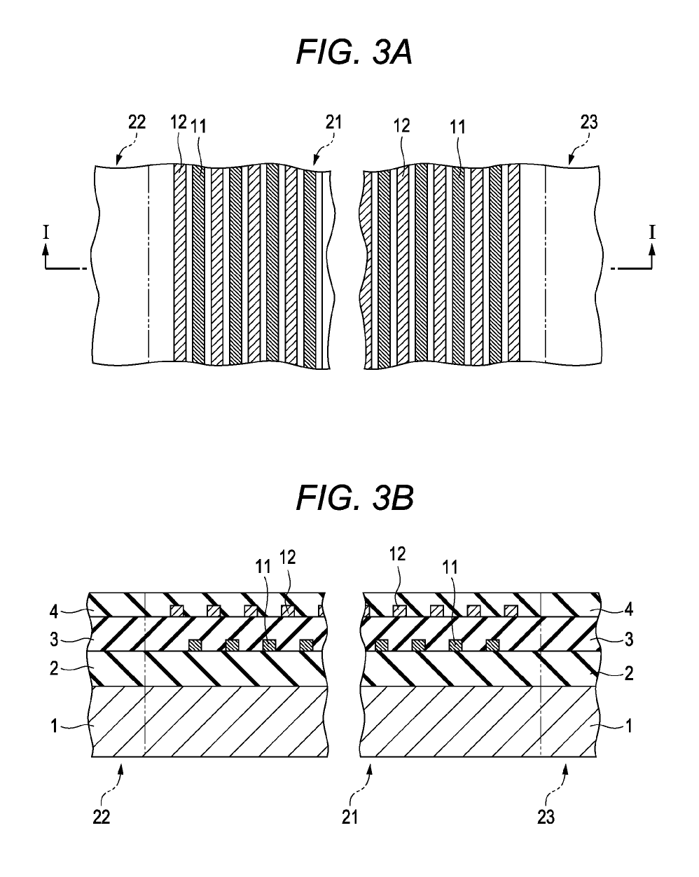

First, a first embodiment will be explained. FIGS. 3A and 3B are views of a semiconductor device according to the first embodiment. Note that FIG. 3B is a sectional view along a line I-I of FIG. 3A.

The semiconductor device according to the first embodiment is partitioned to chip regions by scribe regions extending longitudinally and laterally when viewed on a plane. FIGS. 3A and 3B illustrate a scribe region 21 and chip regions 22 and 23 having the scribe region 21 sandwiched therebetween. That is, the scribe region 21 is formed between the chip regions 22 and 23. Two scan regions, which are to be scanned by a laser beam radiated thereto, are formed in the scribe region 21. A spot, to which the laser beam is radiated, has a diameter of, for example, about 20 μm to 40 μm, and the scan regions also have a width of about 20 μm to 40 μm. Further, the scribe region 21 has a width of about 50 μm to 200 μm.

In the scribe region 21, an insulation film 2 is formed on a semiconductor substrate 1, and strip-shaped metal films 11, which extend parallel to the scribe region 21, are formed on the insulation film 2. Further, an optically-transparent insulation film 3, which covers the metal films 11, is formed on the insulation film 2, and strip-shaped metal films 12, which extend parallel to the scribe region 21, are formed thereon. That is, the metal films 11 and 12 are disposed in a stripe state. Further, an optically-transparent insulation film 4 covering the metal films 12 is formed on the optically-transparent insulation film 3. The optically-transparent insulation films 3 and 4 are composed of, for example, a silicon oxide film, a silicon oxide nitride film, or the like and cause a laser beam to transmit therethrough. The metal films 11 and 12 are composed of, for example, Cu (copper), Cu alloy, Al (aluminum), Al alloy, or the like and have a width of about 0.5 μm to 5 μm and a thickness of about 0.1 μm to 2 μm. Intervals between the metal films 11 and intervals between the metal films 12 are about 0.1 μm to 2 μm, respectively. The optically-transparent insulation film 3 has a thickness of about 0.1 μm to 2 μm on the metal films 11.

Further, the metal films 12 and the metal films 11 are disposed in the scribe region 21 at positions where they are offset from each other when viewed on a plane. That is, the positions of the metal films 11 in a direction parallel to a surface of the semiconductor substrate 1 are offset from the positions of the metal films 12 in the same direction so that a laser beam may reach both the metal films 11 and the metal films 12, which are disposed below the metal films 11, from thereabove. Therefore, since the laser beam may be radiated to the metal films 11 and 12 at the same time as described later, explosion may be caused in many regions in the scribe region 21 in a short time.

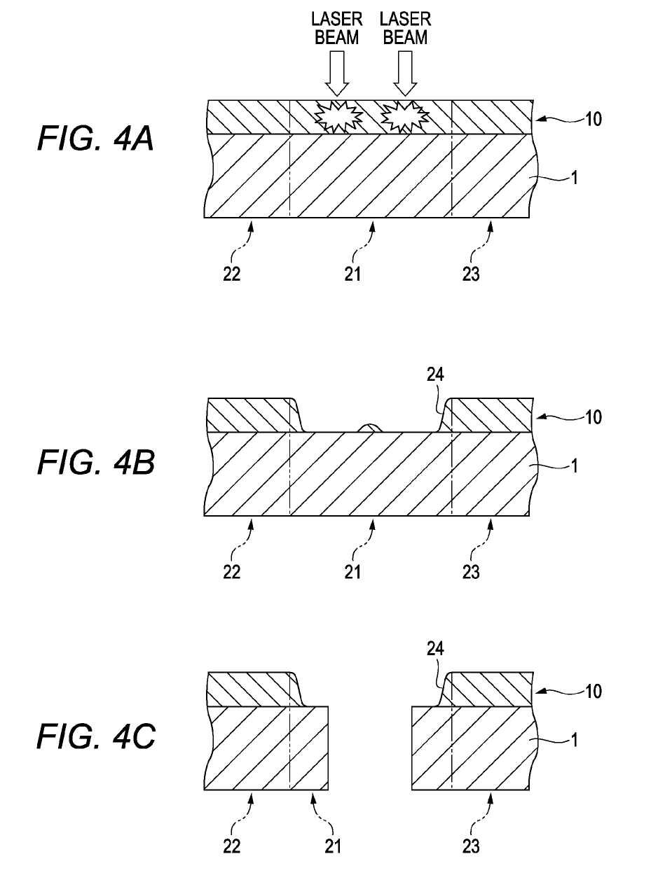

Next, a method of manufacturing a semiconductor integrated circuit chip using the semiconductor device according to the first embodiment will be explained. FIGS. 4A to 4C are sectional views of the method of manufacturing the semiconductor integrated circuit chip in a sequence of steps. Note that FIGS. 4A to 4C illustrate laminated members such as the insulation film 2 disposed on the semiconductor substrate 1 in FIG. 3 as a laminated portion 10.

First, a back surface of the semiconductor substrate 1 is bonded onto a table using an adhesive tape or the like. Next, as illustrated in FIG. 4A, the laser beam is radiated to portions, which are located inside the scribe region 21 away from its edge by a predetermined distance, i.e., to the scan regions, and an irradiation position is moved in a direction where the scribe region 21 extends. That is, a scan is executed by radiating the laser beam. The diameter of the spot to which the laser beam is radiated is, for example, about 20 μm to 40 μm as described above. When the width of the scribe region 21 is 90 μm, first, a scan is executed to portions about 20 μm to 30 μm inside of the scribe region 21 from one edge thereof and thereafter a scan is executed to portions about 20 μm to 30 μm inside of the scribe region 21 from the other edge thereof. As a result, when energy is absorbed to the metal films 11 and 12 in the regions to which the laser beam is radiated and an amount of absorption of the energy reaches a predetermined value, the metal films 11 and 12 are exploded.

When the metal films 11 and 12 are exploded, since the insulation film 2 in the periphery of the metal films 11 and 12 and the optically-transparent insulation films 3, 4 are also blown off, a groove 24 is formed in the laminated portion 10 in the scribe region 21 as illustrated in FIG. 4B.

Next, a rotating blade is inserted into the groove 24, and the semiconductor substrate 1 is cut off from the groove as illustrated in FIG. 4C.

When a cut is executed by radiating the laser beam and using the blade, the chip regions partitioned by the scribe region are cut off to respective pieces and semiconductor integrated circuit chips may be obtained. Note that the method described above may be also applied to second to sixth embodiments to be described later.

According to the first embodiment, since the metal films 11 and 12 of two layers may be exploded by radiating the laser beam once, a time necessary for dicing may be reduced.

### Second Embodiment

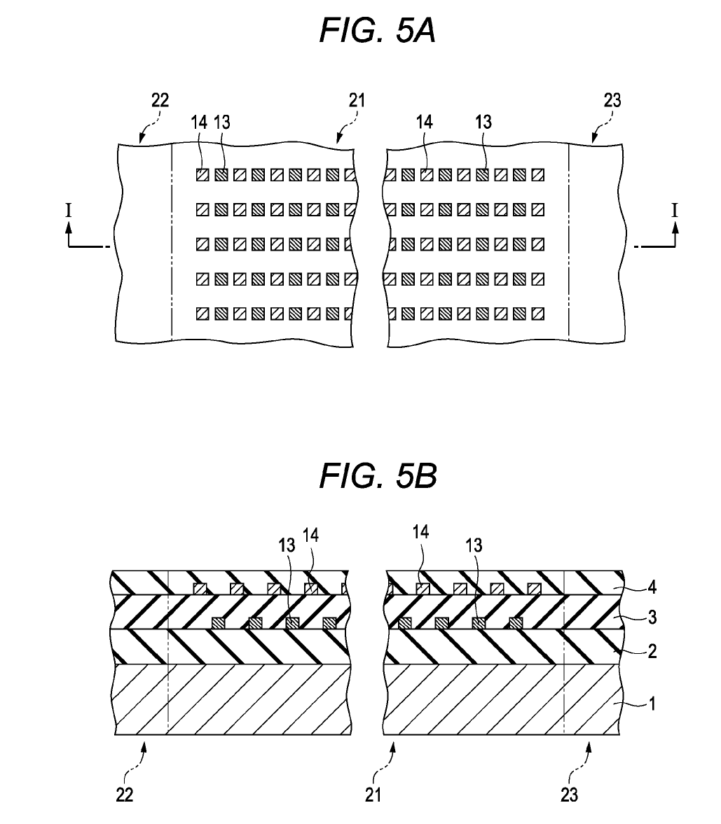

Next, a second embodiment will be explained. FIGS. 5A and 5B are views of a semiconductor device according to the second embodiment. Note that FIG. 5B is a sectional view along a line I-I of FIG. 5A.

The semiconductor device according to the second embodiment is partitioned to chip regions by scribe regions which extend longitudinally and laterally when viewed on a plane as in the first embodiment. FIGS. 5A and 5B illustrate a scribe region 21 and chip regions 22 and 23 having the scribe region 21 sandwiched therebetween. In the second embodiment, rectangular metal films 13 are formed in place of the metal films 11 in the first embodiment and rectangular metal films 14 are formed in an island state in place of the metal films 12 in the first embodiment, respectively. The metal films 13 and 14 are formed in the island state. The metal films 13 and 14 are composed of, for example, Cu, Cu alloy, Al, Al alloy, or the like and have a side length of about 0.5 μm to 5 μm and a thickness of about 0.1 μm to 2 μm. Intervals between the metal films 13 and intervals between the metal films 14 are about 0.1 μm to 2 μm, respectively. An optically-transparent insulation film 3 on the metal films 13 has a thickness of about 0.1 μm to 2 μm. The other configuration of the second embodiment is the same as that of the first embodiment.

According to the second embodiment, the same advantage as that of the first embodiment may be obtained. Since the metal films 13 and 14 are formed in the island state and heat is less escaped, they may be more easily exploded than the metal films 11, 12 of the first embodiment.

### Third Embodiment

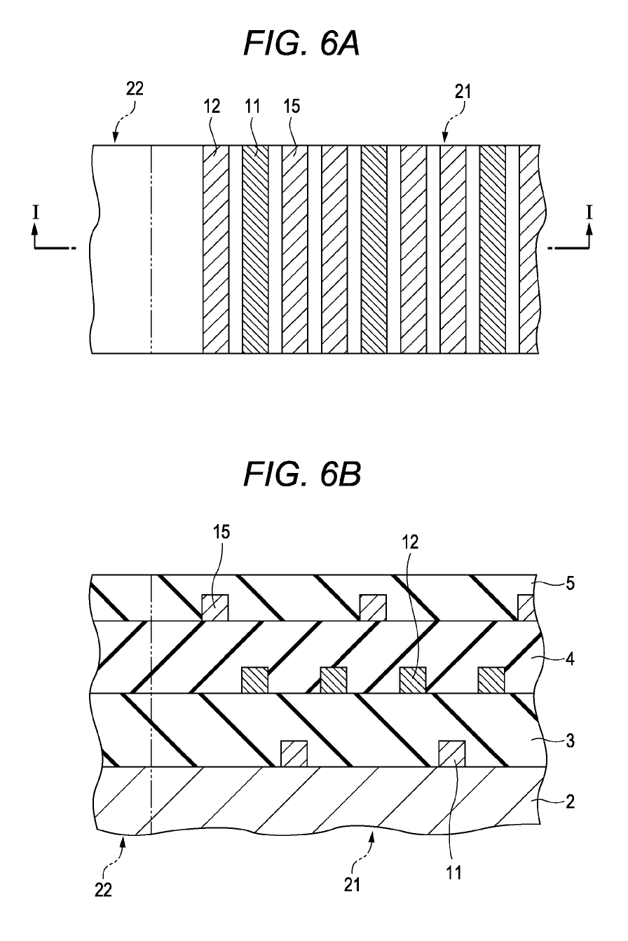

Next, a third embodiment will be explained. FIGS. 6A and 6B are views of a semiconductor device according to the third embodiment. Note that FIG. 6B is a sectional view along a line I-I of FIG. 6A.

The semiconductor device according to the third embodiment is also partitioned to chip regions by scribe regions which extend longitudinally and laterally when viewed on a plane as in the first embodiment. FIGS. 6A and 6B illustrate a scribe region 21 and a chip region 22. Note that a chip region 23 is also formed as in the first embodiment. In the third embodiment, strip-shaped metal films 15, which extend parallel to the scribe region 21, are formed on an optically-transparent insulation film 4. The metal films 15 are also disposed in a stripe state as in the metal films 11 and 12. Further, an optically-transparent insulation film 5, which covers the metal films 15, is formed on the optically-transparent insulation film 4. The optically-transparent insulation film 5 is also composed of, for example, a silicon oxide film, a silicon oxide nitride film, or the like as in the optically-transparent insulation films 3 and 4 and causes a laser beam to transmit therethrough. The metal films 15 are composed of, for example, Cu, Cu alloy, Al, Al alloy, or the like and have a side length of about 0.5 μm to 5 μm and a thickness of about 0.1 μm to 2 μm. Intervals between the metal films 11, intervals between the metal films 12, and intervals between the metal films 15 are about 0.1 μm to 2 μm, respectively. The optically-transparent insulation film 4 has a thickness of about 0.1 μm to 2 μm on the metal films 12. Note that although FIGS. 6A and 6B illustrate a portion of the scribe region 21 on the chip region 22 side, the metal films 11, 12, 15 are also disposed on the chip region 23 side. The other configuration of the third embodiment is the same as that of the first embodiment.

According to the third embodiment, since the metal films 11, 12, and 15 of three layers may be exploded by radiating the laser beam once, a time necessary to dicing may be more reduced than that of the first embodiment.

Note that the metal films 13 and 14 may be used in place of the metal films 11 and 12, the metal films 15 may have a rectangular shape similar to those of the metal films 13 and 14, and the metal films 15 may be disposed in an island state.

### Fourth Embodiment

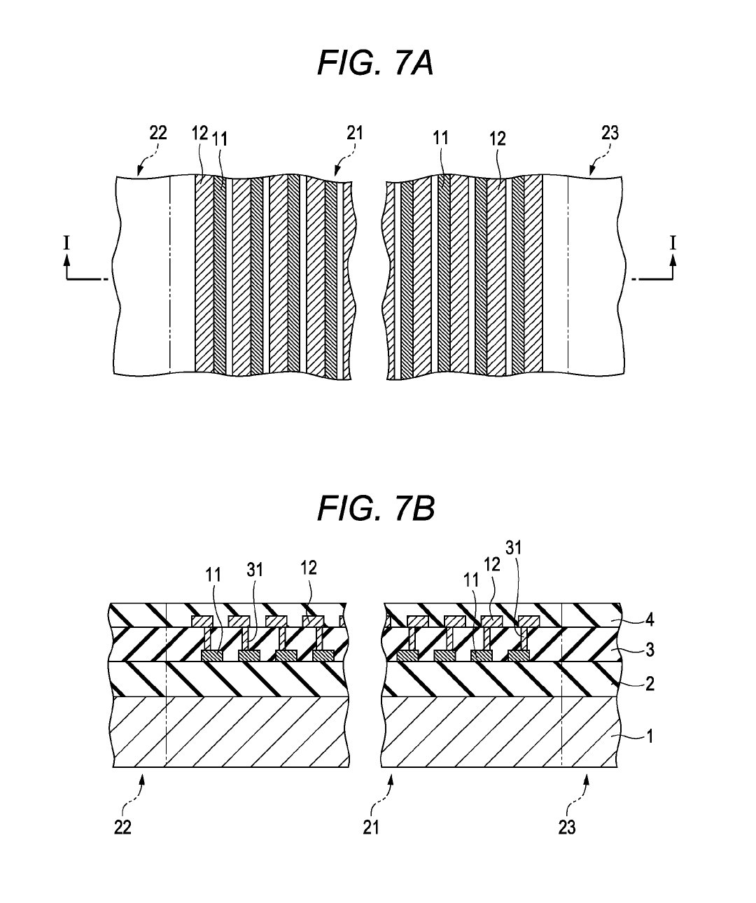

Next, a fourth embodiment will be explained. FIGS. 7A and 7B are views of a semiconductor device according to the fourth embodiment. Note that FIG. 7B is a sectional view along a line I-I of FIG. 7A.

The semiconductor device according to the fourth embodiment is also partitioned to chip regions by scribe regions which extend longitudinally and laterally when viewed on a plane as in the first embodiment. FIGS. 7A and 7B illustrate a scribe region 21 and chip regions 22 and 23 having the scribe region 21 sandwiched therebetween. In the fourth embodiment, since metal films 11 and 12 have a width larger than that of the first embodiment, they have portions overlapping with each other when viewed on a plane. Then, conductive plugs 31 for connecting the overlapping portions are formed. The plugs 31 are composed of metal of, for example, W (tungsten), Al, Cu, and the like. The other configuration of the fourth embodiment is the same as that of first embodiment.

According to the fourth embodiment, the same advantage as that of the first embodiment may be obtained. Further, even if a laser beam radiated to the metal films 11 is partly reflected, since the reflected laser beam is absorbed by the plug 31, a laser beam absorption efficiency may be more improved than that of the first embodiment.

Note that rectangular metal films 13 and 14 may be used in place of the metal films 11 and 12.

### Fifth Embodiment

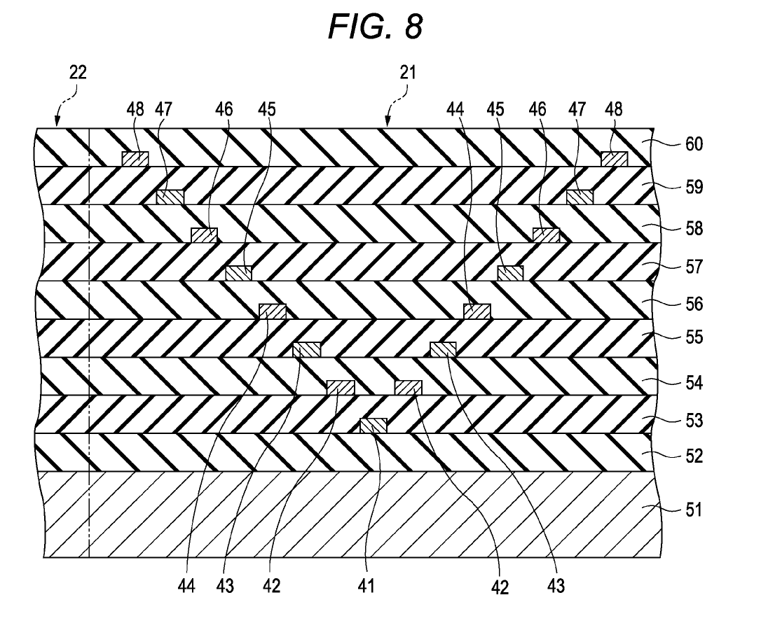

Next, a fifth embodiment will be explained. FIG. 8 is a sectional view of a semiconductor device according to the fifth embodiment. FIG. 8 illustrates a cross section orthogonal to a direction in which a scribe region 21 extends as in FIG. 3B and the like. Further, although FIG. 8 illustrates the scribe region 21 and a chip region 22 as in FIG. 6, a chip region 23 is also formed as in the first embodiment.

In the fifth embodiment, metal films 41 to 48 are dispose so that they are offset from each other when viewed on a plane in a region having a width (for example, about 25 μm) equal to or less than a diameter (for example, about 30 μm) of a radiation spot of a laser beam as illustrated in FIG. 8. The metal films 41 to 48 have a stripe shape similar to that of, for example, the metal films 11, 12, and 15 and extend parallel to the scribe region 21. Note that although FIG. 8 illustrates a portion on the chip region 22 side of the scribe region 21, the metal films 41 to 48 are also disposed on the chip region 23 side. Further, two pieces each of the metal films 42 to 48 are disposed in one piece of the metal film 41 on each of the chip region 22, 23 sides, and the metal films 42 to 48 are disposed in this order when viewed on a plane so that they are away from the metal film 41. That is, the metal films 41 to 48 are disposed in a “V shape” on a cross section orthogonal to a direction in which the scribe region 21 extends.

Further, in the scribe region 21, an insulation film 52 is formed on a semiconductor substrate 51, and the metal film 41 is formed on the insulation film 52. Further, an optically-transparent insulation film 53, which covers the metal films 41, is formed on the insulation film 52, and the metal films 42 are formed on the optically-transparent insulation film 53. Further, an optically-transparent insulation film 54, which covers the metal films 42, is formed on the optically-transparent insulation film 53. The metal films 43 are formed on the optically-transparent insulation film 54, and further an optically-transparent insulation film 55, which covers the metal films 43, is also formed on the optically-transparent insulation film 54. The metal films 44 are formed on the optically-transparent insulation film 55, and an optically-transparent insulation film 56, which covers the metal films 44, is also formed on the optically-transparent insulation film 55. The metal films 45 are formed on the optically-transparent insulation film 56, and further an optically-transparent insulation film 57, which covers the metal films 45, is also formed on the optically-transparent insulation film 56. The metal films 46 are formed on the optically-transparent insulation film 57, and further an optically-transparent insulation film 58, which covers the metal films 46, is also formed on the optically-transparent insulation film 57. The metal films 47 are formed on the optically-transparent insulation film 58, and further an optically-transparent insulation film 59, which covers the metal films 47, is also formed on the optically-transparent insulation film 58. Further, the metal films 48 are formed on the optically-transparent insulation film 59, and further an optically-transparent insulation film 60, which covers the metal film 48, is also formed on the optically-transparent insulation film 59.

The metal films 41 to 43 are composed of, for example, Cu and have a width of about 0.7 μm and a thickness of about 0.3 μm. The optically-transparent insulation films 53 and 55 are composed of, for example, a silicon oxide nitride film and cause a laser beam to transmit therethrough. The optically-transparent insulation films 53 to 55 have a thickness of about 0.3 μm on the metal films 41 to 43. The metal films 44 and 45 are composed of, for example, Cu and have a width of about 0.7 μm and a thickness of about 0.5 μm. The optically-transparent insulation films 56 and 57 are composed of, for example, a silicon oxide nitride film and cause a laser beam to transmit therethrough. The optically-transparent insulation films 56 and 57 have a thickness of about 0.5 μm on the metal films 44 and 45. The metal films 46 and 47 are composed of, for example, Cu and have a width of about 1 μm and a thickness of about 1 μm. The optically-transparent insulation films 58 and 59 are composed of, for example, a silicon oxide film and causes a laser beam to transmit therethrough. The optically-transparent insulation films 58 and 59 have a thickness of about 0.6 μm on the metal films 46 and 47. The metal film 48 is composed of, for example, Al and have a width of about 2 μm and a thickness of about 1 μm. The optically-transparent insulation film 60 is composed of, for example, a silicon oxide film and causes a laser beam to transmit therethrough. The optically-transparent insulation film 60 has a thickness of about 0.8 μm on the metal films 48.

According to the fifth embodiment, since the metal films 41 to 48 of eight layers may be exploded by radiating a laser beam once, a time necessary for dicing may be more reduced. Further, since an increase in the number of the metal films makes a laser beam more unlikely to leak to the chip regions 22 and 23, damage and the like to chips, such as cracks, due to the leakage of the laser beam may be suppressed.

Note that the metal films 41 to 47 may have a rectangular shape similar to that of the metal films 13 and 14 and may be disposed in an island state.

### Sixth Embodiment

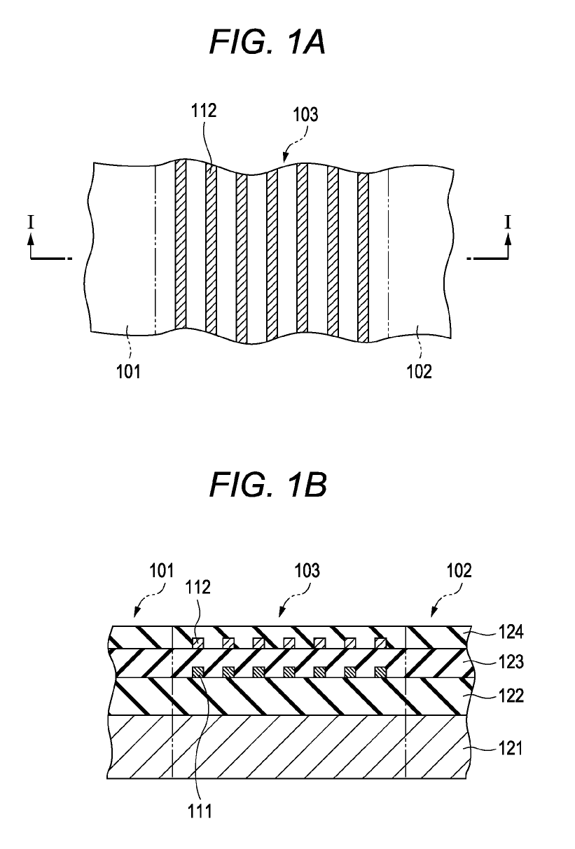

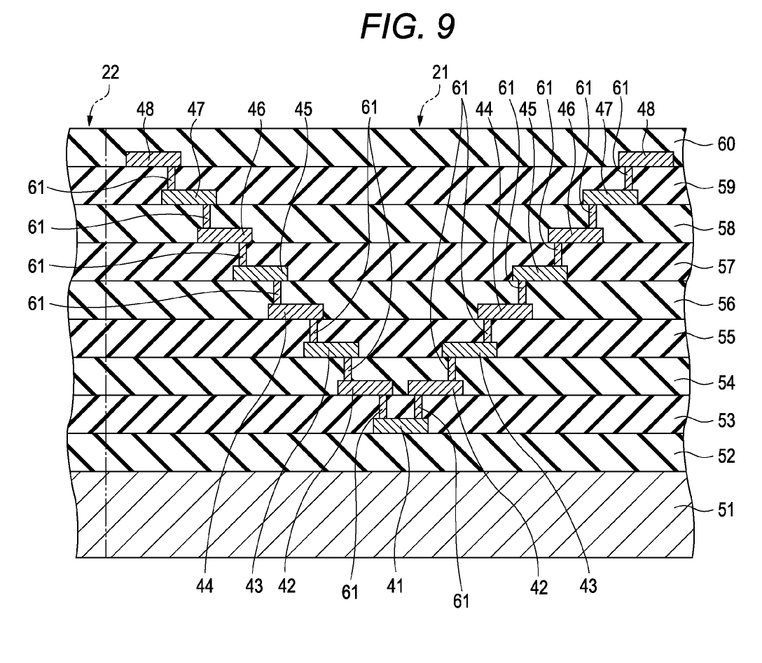

Next, a sixth embodiment will be explained. FIG. 9 is a sectional view of a semiconductor device according to the sixth embodiment. FIG. 9 illustrates a cross section orthogonal to a direction in which a scribe region 21 extends as in FIG. 1B and the like. Further, although FIG. 9 illustrates the scribe region 21 and a chip region 22 as in FIG. 6, a chip region 23 is also formed as in the first embodiment.

In the sixth embodiment, since metal films 41 to 48 have a width larger than that of the fifth embodiment as in the fourth embodiment, they have portions overlapping with each other when viewed on a plane. Then, conductive plugs 61 for connecting the overlapping portions are formed. The plugs 61 are composed of metal of, for example, W (tungsten), Al, Cu, and the like. The other configuration of the sixth embodiment is the same as that of fifth embodiment.

According to the sixth embodiment, the same advantage as that of the fifth embodiment may be obtained. Further, even if a laser beam radiated to the metal films 41 to 48 is partly reflected, since the reflected laser beam is absorbed by the plugs 61, a laser beam absorption efficiency may be improved over that of the fifth embodiment.

Note that although the metal films are disposed by being offset between the layers in the direction orthogonal to the direction in which the scribe region 21 extends in the first to sixth embodiments, the direction in which the metal films are offset is not particularly limited to the above direction. For example, the metal films may be offset in parallel to the direction in which the scribe region 21 extends. That is, it is sufficient that a laser beam is radiated to the metal films of the layers by being radiated once.

Further, it is not necessary that the optically-transparent films be the insulation films in the scribe region 21.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to the superiority and inferiority of the invention. Although the embodiment(s) of the present inventions have been described in detail, it should be understood that various changes, substitutions, and alterations could be made hereto without departing from the spirit and scope of the invention.

What is claimed is:

1. A semiconductor device comprising:
a plurality of circuit regions formed in a semiconductor substrate; and
a scribe region formed around the circuit regions for separating the respective circuit regions, the scribe region having a plurality of laminated interlayer films including a plurality of metal films and an optically-transparent insulation film formed between and on the plurality of metal films,
wherein a first metal film included in a first upper interlayer film of the plurality of interlayer films is positionally offset in a vertical direction to a second metal film included in a second lower interlayer film under the first interlayer film.

2. The semiconductor device according to claim 1, wherein only a portion of the first metal film directly overlaps the second metal film in a vertical direction, and the first metal film is connected to the second metal film in the overlapping portion by a conductive member.

3. The semiconductor device according to claim 1, wherein the plurality of metal films are composed of a plurality of strip-shaped metal films disposed in parallel with each other.

4. The semiconductor device according to claim 1, wherein the plurality of metal films are composed of a plurality of rectangular metal films disposed in an island state.

5. The semiconductor device according to claim 1, wherein the optically-transparent insulation film is transparent to a laser beam.

6. The semiconductor device according to claim 1, wherein the optically-transparent insulation film is a silicon oxide film or a silicon oxide nitride film.

7. The semiconductor device according to claim 1, wherein the first metal film is interposed between at least two second metal films.

8. The semiconductor device according to claim 1, further comprising a third metal film included in a third interlayer film under the second interlayer film,
wherein the third metal film is located at a position where it does not directly overlap the second metal film, and
the first metal film is located at a position where it does not directly overlap the second and third metal films.

9. A method of manufacturing a semiconductor chip, comprising a step of radiating a laser beam to a first metal film and a second metal film at the same time and exploding the first and second metal films in a semiconductor substrate;
said substrate having a plurality of circuit regions and a scribe region formed around the circuit regions for separating the respective circuit regions, the scribe region having a plurality of laminated interlayer films including a plurality of metal films and optically-transparent insulation films formed between and on the plurality of metal films, wherein the first metal film is included in a first upper interlayer film of the plurality of interlayer films and is located at a position where it does not directly overlap the second metal film included in a second lower interlayer film under the first interlayer film in a vertical direction.

10. The method of manufacturing a semiconductor chip according to claim 9, further comprising a step of cutting off the scribe region using a blade.
